(19) United States
(12) Patent Application Publication
(10) Pub. No.: US 2025/0349765 A1
(43) Pub. Date: Nov. 13, 2025

(54) Semiconductor structure including hybrid bond contact and manufacturing method thereof

(71) Applicant: UNITED MICROELECTRONICS CORP., Hsin-Chu City (TW)

(72) Inventors: Chiao-Hui Tu, Tainan City (TW); Chiu-Jung Chiu, Tainan City (TW); Yi-An Shih, Changhua County (TW); Chuan-Lan Lin, Chiayi City (TW); Yen-Tsai Yi, Tainan City (TW); Wei-Chuan Tsai, Changhua County (TW); Chun-Ling Lin, Tainan City (TW); Chu-Fu Lin, Kaohsiung City (TW); Teng-Chuan Hu, Tainan City (TW); Chun-Hung Chen, Tainan City (TW)

(73) Assignee: UNITED MICROELECTRONICS CORP., Hsin-Chu City (TW)

(21) Appl. No.: 18/747,495

(22) Filed: Jun. 19, 2024

(30) Foreign Application Priority Data
May 8, 2024 (TW) 113116939

(51) Int. Cl. H01L 23/00

(52) U.S. Cl. CPC H01L 24/05; H01L 24/08; H01L 24/80; H01L 2224/05083; H01L 2224/05087; H01L 2224/05091; H01L 2224/05098; H01L 2224/05147; H01L 2224/05166; H01L 2224/05181; H01L 2224/08145; H01L 2224/80895; H01L 2224/80896; H01L 2924/01013; H01L 2924/01022; H01L 2924/01073; H01L 2924/01327; H01L 2924/04941; H01L 2924/04953; H01L 2924/30101

(57) ABSTRACT

The present invention provides a semiconductor structure containing a hybrid bond contact, comprising a first hybrid bond contact located in a dielectric layer. The first hybrid bond contact is consisting of copper. A first top wiring layer is situated within the dielectric layer and below the first hybrid bond contact, wherein the first top wiring layer is made of aluminum. A first composite liner layer is positioned between the first hybrid bond contact and the first top wiring layer. From a cross-sectional view, the first composite liner layer encapsulates the sidewalls and bottom surface of the first hybrid bond contact. The first composite liner layer consists of a titanium layer, a titanium nitride layer, a tantalum nitride layer, and a tantalum layer.

### BACKGROUND OF THE INVENTION

### 1. Field of the Invention

The present invention relates to the field of semiconductors, particularly to a semiconductor structure containing a hybrid bond contact and its fabrication method, with the effect of reducing the interface resistance between copper and aluminum.

### 2. Description of the Prior Art

In known technology, common chip packaging methods include chip on film (COF), chip on glass (COG), or chip on plastic (COP).

With the advancement of technology, semiconductor device dimensions are gradually shrinking and becoming more refined, rendering the aforementioned packaging methods inadequate to meet current technological demands. There is a need to develop packaging methods with higher precision and smaller dimensions to meet practical usage requirements.

In current technology, hybrid bonding is a commonly used technique. For example, contact structures formed on two different substrates can be brought into contact and electrically connected through hybrid bonding. This bonding method can significantly reduce area and increase component density compared to methods like wire bonding or solder ball formation, making hybrid bonding increasingly prevalent in the semiconductor manufacturing field.

### SUMMARY OF THE INVENTION

This invention provides a semiconductor structure containing a hybrid bond contact, comprising a first hybrid bond contact located in a dielectric layer. The first hybrid bond contact is made of copper, and a first top wiring layer is situated within the dielectric layer and below the first hybrid bond contact. The first top wiring layer is made of aluminum. Additionally, a first composite buffer layer is positioned between the first hybrid bond contact and the first top wiring layer. From a cross-sectional view, the first composite buffer layer encapsulates the two sidewalls and the bottom surface of the first hybrid bond contact. This first composite buffer layer consists of four layers: a titanium layer, a titanium nitride layer, a tantalum nitride layer, and a tantalum layer.

Furthermore, the invention provides a method for manufacturing a semiconductor structure containing a hybrid bond contact. This method involves forming a first hybrid bond contact within a dielectric layer, with the first hybrid bond contact made of copper. Additionally, a first top wiring layer, composed of aluminum, is formed within the dielectric layer and below the first hybrid bond contact. A first composite buffer layer is then formed between the first hybrid bond contact and the first top wiring layer. Similar to the structure, from a cross-sectional view, the first composite buffer layer encompasses the two sidewalls and the bottom surface of the first hybrid bond contact and consists of a titanium layer, a titanium nitride layer, a tantalum nitride layer, and a tantalum layer.

The distinguishing feature of this semiconductor structure and its manufacturing method lies in the addition of a buffer layer when there is an interface between copper and aluminum components within the semiconductor structure. This buffer layer, comprising four layers, effectively reduces the interface resistance between the copper and aluminum components. Moreover, during heating processes, an additional aluminum-titanium layer forms between the aluminum component and the titanium layer, effectively blocking aluminum atoms from diffusing into other components during the manufacturing process, thereby improving the quality and yield of the components.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 depicts a schematic diagram of the semiconductor structure of the present invention along with an enlarged partial structure.

FIG. 2 illustrates an enlarged sectional schematic diagram near the copper-aluminum interface of another embodiment of the semiconductor structure according to the present invention.

FIG. 3 shows a sectional schematic diagram of the bonding structure between different chips according to an embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

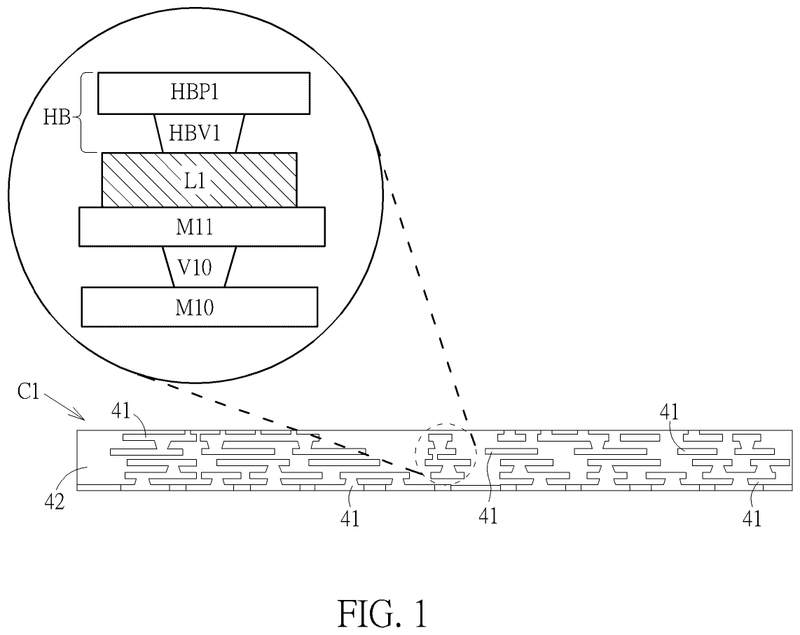

Please refer to FIG. 1, which illustrates a schematic diagram and a partial enlarged view of the semiconductor structure of the present invention. As shown in FIG. 1, multiple metal layers 41 are formed in the dielectric layer 42 of a semiconductor chip C1. The metal layers 41 include metal wiring layers extending horizontally and hybrid bond vias penetrating the dielectric layer vertically. The left half of FIG. 1 depicts a partial enlarged view of the semiconductor chip 1, where some of the metal layers are labeled as metal wiring layer M11, hybrid bond via V10, and metal wiring layer M10. It's worth noting that beneath the metal wiring layer M10, there may be additional hybrid bond vias or metal wiring layers (such as the metal layer 41 shown in the right half of FIG. 1). Additionally, different metal wiring layers and hybrid bond vias may dispose in different layers of the dielectric material, which may include insulating materials such as silicon nitride, silicon oxide, or silicon oxynitride. However, for the sake of simplicity, FIG. 1 omits other hybrid bond vias or metal wiring layers beneath the metal wiring layer M10. Generally, the numbers associated with the metal wiring layers M10, hybrid bond via V10, and metal wiring layer M10 indicate the order in which they are stacked from bottom to top in the semiconductor structure. For example, the metal wiring layer M11 represents the 11th layer of metal wiring in the semiconductor structure. However, it's understood that the number of stacked metal wiring layers or hybrid bond vias may vary depending on different semiconductor structures. FIG. 1 represents just one example, and the actual number of stacked metal wiring layers or hybrid bond vias may vary according to specific requirements. In other words, the topmost metal wiring layer depicted in FIG. 1 may be M11, M8, M9, M12, M15, or Mx (where x represents any other positive integer) in other embodiments, all falling within the scope of the present invention.

The preferred material for the metal wiring layers or hybrid bond vias described in FIG. 1 is copper. Copper is preferred due to its excellent conductivity, making it commonly used in fabricating wiring layers in semiconductor structures. However, copper tends to oxidize when exposed to air, leading to a significant decrease in conductivity. Therefore, it's preferable to fabricate the mentioned process under an oxygen-free environment. However, this complicates the quality testing of the metal wiring layers.

As depicted in FIG. 1 of the present invention, a top wiring layer L1, composed of aluminum, is formed on the surface of the metal wiring layer M11. The top wiring layer L1 can be considered as the topmost layer of metal wiring layers in the semiconductor structure. That is to say, in a semiconductor structure containing multiple layers of metal wiring and hybrid bond vias for connecting various electronic components, except for the topmost top wiring layer L1, the material of the remaining metal wiring layers and hybrid bond vias beneath is preferably copper. This means that after the fabrication of multiple layers of metal wiring layers, only the topmost top wiring layer L1 is exposed to air, while other metal wiring layers or hybrid bond vias will be covered or buried in the dielectric layer without direct exposure to air.

After the completion of the top wiring layer L1 and before the formation of subsequent components, the present invention allows for an electrical testing step to be conducted on the multiple layers of metal wiring layers. As mentioned earlier, aluminum is less reactive with air compared to copper, making it more suitable for electrical testing exposed to air. Electrical testing may include tests for circuit continuity or resistance. If the test results meet the specified criteria, the subsequent steps can proceed. Conversely, if the test results do not meet the criteria, it indicates that there may be issues or damage with these multiple layers of metal wiring layers. At this point, process adjustments may be made to identify the problematic process or parameters, and the damaged semiconductor structure may be discarded or recycled.

If the aforementioned electrical testing step passes, as shown in FIG. 1, the subsequent step involves the formation of hybrid bonding contacts HB on the top wiring layer L1. The hybrid bonding contact HB comprises a hybrid bond via HBV1 and a hybrid bond pad HBP1. Both the hybrid bond via HBV1 and the hybrid bond pad HBP1 are preferably made of copper. The area of the hybrid bond pad HBP1 is preferably larger than that of the hybrid bond via HBV1, but this is not limited. In this embodiment, the hybrid bond via HBV1 is used to connect the hybrid bond pad HBP1 to the top wiring layer L1, while the hybrid bond pad HBP1 is used to connect to another semiconductor structure, such as another semiconductor structure containing multiple layers of wiring layers and hybrid bond pads. The two semiconductor structures connect face-to-face with their respective hybrid bond pads, a method known as hybrid bonding. Compared to other types of packaging methods in semiconductor processes (such as solder packaging, wire bonding, etc.), hybrid bonding can effectively increase the density of components and reduce the volume of components.

In the stack structure of the components described above, the purpose of forming the top wiring layer L1 is to avoid oxidation of the topmost metal layer (i.e., the top wiring layer L1) during the electrical testing step, which could affect the test results. Therefore, it is necessary to form the top wiring layer L1 in the process. However, the inventors have found that the material of the metal layer below the top wiring layer L1 (such as the metal wiring layer M11) and the material of the metal layer above it (such as the hybrid bond via HBV1) are both copper, and the combination of copper and aluminum, these two different metals, tends to increase interface resistance when bonded, which is detrimental to the quality of the components.

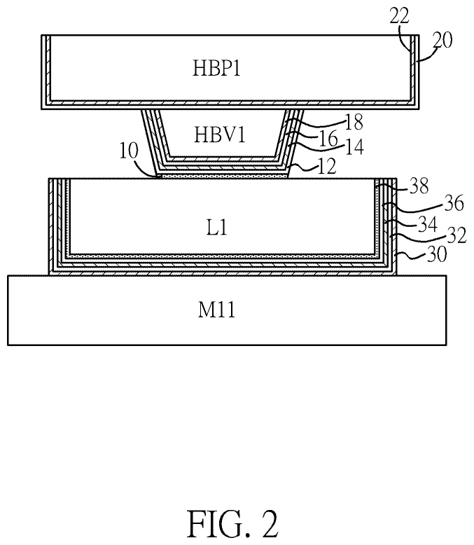

Therefore, the inventors have made improvements to the copper-aluminum interface to increase its conductivity and improve the quality of the components. Specifically, please refer to FIG. 2, which illustrates an enlarged cross-sectional schematic diagram near the copper-aluminum interface of another embodiment of the semiconductor structure according to the present invention. As shown in FIG. 2, in this embodiment, multiple material layers have been added between the aluminum component (such as the aforementioned top wiring layer L1) and the copper component (such as the hybrid bond via HBV1). In this embodiment, multiple material layers have been added between the top wiring layer L1 and the hybrid bond via HBV1, including a titanium (Ti) layer 12, a titanium nitride (TiN) layer 14, a tantalum nitride (TaN) layer 16, and a tantalum (Ta) layer 18 from bottom to top. It should be noted that in general semiconductor technology, the buffer layers formed around the conductive layers are usually only combinations of titanium with titanium nitride, or tantalum with tantalum nitride. In the present invention, a total of four buffer layers are arranged between the aluminum component and the copper component, namely the titanium (Ti) layer 12, the titanium nitride (TiN) layer 14, the tantalum nitride (TaN) layer 16, and the tantalum (Ta) layer 18. Each buffer layer appears as a U-shaped structure in the cross-sectional view, sequentially wrapping the bottom and sidewalls of the hybrid bond via HBV1 from the inside out. According to the experimental results of the inventors, compared to the conventional technique of forming only two buffer layers (such as a titanium layer with a titanium nitride layer, or a tantalum layer with a tantalum nitride layer), using four buffer layers can effectively reduce the interface resistance between the copper component and the aluminum component, thereby improving the quality of the components.

Furthermore, since the top wiring layer L1 directly contacts the titanium layer 12, the process temperature will be raised to above 100 degrees Celsius during the formation of other material layers. At this time, an aluminum-titanium intermetallic (TiAl₃) layer 10 will be formed between the top wiring layer L1 and the titanium layer 12. From the cross-sectional view, the aluminum-titanium layer 10 appears as a “-” shape, meaning that the aluminum-titanium layer 10 does not have a U-shaped structure like the titanium layer 12, the titanium nitride layer 14, the tantalum nitride layer 16, and the tantalum layer 18. Instead, it has a flat structure. Therefore, the aluminum-titanium layer 10 only contacts the bottom surface of the titanium layer 12, and does not contact the sidewalls of the titanium layer 12.

As for the periphery of the top wiring layer L1 and the hybrid bond via HBV1, buffer layers are also formed. However, if it is not the junction interface between a copper component and an aluminum component, but rather the interface between two copper components, then it is not necessary to form the four-layer buffer layers as described above. Instead, only a combination of a titanium layer with a titanium nitride layer, or a tantalum layer with a tantalum nitride layer is needed. For example, since both the hybrid bond via HBV1 and the hybrid bond pad HBP1 are copper components, only a tantalum nitride layer 20 and a tantalum layer 22 are formed between them as the buffer layers. Similarly, at the junction interface between the top wiring layer L1 and the underlying metal wiring layer M11, a four-layer buffer layer can also be formed, including a tantalum layer 30, a tantalum nitride layer 32, a titanium nitride layer 34, and a titanium layer 36. Similarly, at the interface between the top wiring layer L1 and the titanium layer 36, since aluminum directly contacts titanium, an aluminum-titanium (TiAl₃) layer 38 is formed. This aluminum-titanium layer 38 covers the bottom and sidewalls of the top wiring layer L1, meaning that from the side view, the aluminum-titanium layer 38 appears as a U-shape.

In this embodiment, the thickness of the titanium layer 12 is approximately 500 angstroms, the thickness of the titanium nitride layer 14 is approximately 50 angstroms, the thickness of the tantalum nitride layer 16 is approximately 80 angstroms, and the thickness of the tantalum layer 18 is approximately 50 angstroms. However, the thicknesses of the various components mentioned above are only exemplary for one embodiment of the present invention, and the invention is not limited thereto.

It is worth noting that the aluminum-titanium layer 10 formed above the top wiring layer L1 and the aluminum-titanium layer 38 formed below it also serve to block atomic diffusion. Specifically, during the formation of the hybrid bond via HBV1, aluminum atoms from the top wiring layer L1 may diffuse into other components during heating. The aluminum-titanium layers 10 and 38 formed here serve to prevent aluminum atoms from migrating to the copper components above or below.

In the concept of the present invention described above, if the top wiring layer (i.e., the layer closest to the top, excluding the hybrid bond pad HBP1 and the hybrid bond via HBV1) in the semiconductor chip is made of aluminum, it is necessary to form a four-layer buffer layer to reduce the interface resistance between the copper component and the aluminum component, while also blocking the diffusion of aluminum atoms during heating. However, if the top wiring layer in the semiconductor chip is made of copper, meaning that the underlying metal wiring layer, the top wiring layer, and the upper hybrid bond pad and hybrid bond via are all copper components, there is no need to form a four-layer buffer layer. Instead, it is sufficient to form, for example, a tantalum layer and a tantalum nitride layer between the copper components.

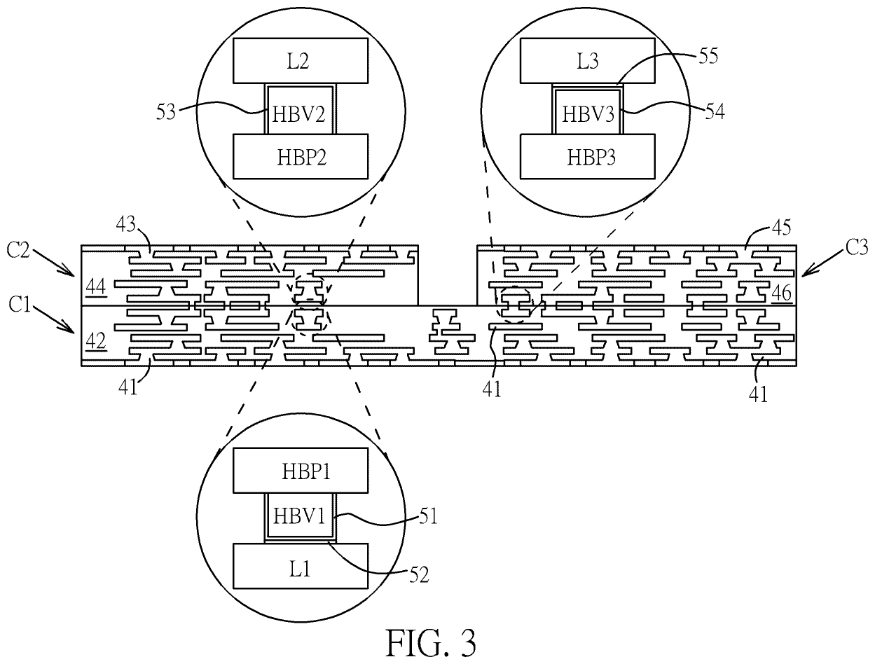

FIG. 3 illustrates a cross-sectional schematic diagram of bonding different chips to each other according to one embodiment of the present invention. As shown in FIG. 3, a first chip C1, a second chip C2, and a third chip C3 are bonded to each other, with the size of the first chip C1 larger than that of the second chip C2 and the third chip C3. Therefore, the second chip C2 and the third chip C3 are bonded to the first chip C1 simultaneously. The first chip C1 comprises multiple conductive layers 41 within multiple dielectric layers 42, the second chip C2 comprises multiple conductive layers 43 within multiple dielectric layers 44, and the third chip C3 comprises multiple conductive layers 45 within multiple dielectric layers 46. The structure of the conductive layers 41, 43, 45 is similar to the structures such as the metal wiring layer M11, the hybrid bond via V10, and the metal wiring layer M10 described in FIG. 1, while the dielectric layers 42, 44, 46 may be a multi-layer stack of insulating layers such as silicon oxide, silicon nitride, and silicon oxynitride. For simplicity, conductive layers 41, 43, 45 are used to represent multiple conductive layers, and dielectric layers 42, 44, 46 represent multiple dielectric layers.

As mentioned in the previous paragraph, in some processes, forming the top wiring layer (i.e., the layer closest to the top, excluding the hybrid bond pad HBP1 and the hybrid bond via HBV1) in aluminum can prevent oxidation of the device and improve yield during electrical testing. However, in other processes, such as those with higher yield or lower precision requirements, there may be no need for electrical testing steps, so it may be preferable not to use aluminum to form the top wiring layer in multiple conductive layers, and copper may be a better choice. For example, in this embodiment, the top wiring layers L1 and L3 in the first chip Cl and the third chip C3 shown in FIG. 3 are made of aluminum, while the top wiring layer L2 in the second chip C2 is made of copper. Additionally, the other wiring layers contained in each of the first chip C1, the second chip C2, and the third chip C3 are all copper components. That is to say, the hybrid bond via HBV1, the hybrid bond pad HBP1 and the conductive layer 41 included in the first chip C1 are copper elements, the hybrid bond via HBV2, the hybrid bond pad HBP2 and the conductive layer 43 included in the second chip C2 are copper elements, and the hybrid bond via HBV3, the hybrid bond pad HBP3 and the conductive layer 43 included in the third chip C3 are copper elements.

As described in the concept of the present invention, when copper components contact aluminum components, a four-layer buffer layer is required between the copper component and the aluminum component, including a titanium (Ti) layer, a titanium nitride (TiN) layer, a tantalum nitride (TaN) layer, and a tantalum (Ta) layer. The order of arrangement can be referred to as shown in FIG. 2. Furthermore, an aluminum-titanium (TiAl₃) layer is also formed at the junction interface between the titanium layer and the aluminum component. Therefore, as shown in FIG. 3, the first chip C1 comprises a composite buffer layer 51 covering two sidewalls and bottom of the hybrid bond via HBV1, wherein the composite buffer layer 51 comprises a titanium layer, a titanium nitride layer, a tantalum nitride layer, and a tantalum layer, and below the composite buffer layer 51, there is an aluminum-titanium layer 52 located between the top wiring layer L1 and the composite buffer layer 51. Similarly, since the top wiring layer L3 in the third chip C3 is also aluminum, the third chip C3 comprises a composite buffer layer 54 covering two sidewalls and bottom of the hybrid bond via HBV3, wherein the composite buffer layer 54 comprises a titanium layer, a titanium nitride layer, a tantalum nitride layer, and a tantalum layer, and below the composite buffer layer 54, there is an aluminum-titanium layer 55 between the top wiring layer L3 and the composite buffer layer 54. As for the second chip C2, since the top wiring layer L2 is not made of aluminum but copper, the composite buffer layer 53 between the hybrid bond via HBV2 and the top wiring layer L2 does not contain a four-layer structure but is consist of a tantalum nitride layer and a tantalum layer, totaling two layers.

Based on the above description and diagrams, the present invention provides a semiconductor structure with a hybrid bond contact, as illustrated in FIG. 2 or FIG. 3. It includes a first hybrid bond contact (HB), located in a dielectric layer 42, wherein the first hybrid bond contact HB is made of copper; a first top wiring layer L1, located in the dielectric layer 42 and below the first hybrid bond contact HB, wherein the first top wiring layer L1 is made of aluminum; and a first composite buffer layer (i.e., the titanium layer 12, the titanium nitride layer 14, the tantalum nitride layer 16, and the tantalum layer 18 in FIG. 2), located between the first hybrid bond contact HB and the first top wiring layer L1. From a cross-sectional view, the first composite buffer layer covers two sidewalls and a bottom of the first hybrid bond contact HB and is consist of a titanium layer 12, a titanium nitride layer 14, a tantalum nitride layer 16, and a tantalum layer 18.

In some embodiments of the present invention, the titanium layer 12, the titanium nitride layer 14, the tantalum nitride layer 16, and the tantalum layer 18 in the first composite buffer layer are arranged from bottom to top.

In some embodiments of the present invention, there is also an aluminum-titanium (TiAl₃) layer located between the first composite buffer layer and the first top wiring layer L1.

In some embodiments of the present invention, the aluminum-titanium (TiAl₃) layer directly contacts the bottom surface of the first top wiring layer L1 and the titanium layer 12 in the first composite buffer layer.

In some embodiments of the present invention, the aluminum-titanium (TiAl₃) layer does not contact the sidewalls of the titanium layer 12 in the first composite buffer layer.

In some embodiments of the present invention, there is an additional wiring layer (e.g., the wiring layer M11) located below the first top wiring layer L1, wherein the wiring layer M11 is made of copper.

In some embodiments of the present invention, the first hybrid bond contact HB includes an upper portion HBP1 and a lower portion HBV1, wherein the width of the upper portion HBP1 is greater than that of the lower portion HBV1, and the first composite buffer layer covers the bottom surface and sidewalls of the lower portion HBV1.

In some embodiments of the present invention, there is an additional buffer layer (i.e., the tantalum nitride layer 20 and tantalum layer 22 in FIG. 2) covering the bottom surface and sidewalls of the upper portion HBP1 of the first hybrid bond contact HB, wherein the additional buffer layer is consist of a tantalum layer 22 and a tantalum nitride layer 20, and does not contain titanium layer or titanium nitride layer.

In some embodiments of the present invention, the first hybrid bond contact HB, the first top wiring layer L1, and the first composite buffer layer are located in a first chip C1. Additionally, there is a second chip C2 and a third chip C3, where the size of the first chip C1 is larger than that of the second chip C2 and the third chip C3. The first chip C1 is bonded simultaneously with both the second chip C2 and the third chip C3.

In some embodiments of the present invention, the second chip C2 includes a second hybrid bond contact (the hybrid bond via HBV2 and the hybrid bond pad HBP2 shown in FIG. 3), a second top wiring layer L2, and a second buffer layer 53, electrically connected to each other. The third chip C3 includes a third hybrid bond contact (the hybrid bond via HBV3 and the hybrid bond pad HBP3 shown in FIG. 3), a third top wiring layer L3, and a third buffer layer 54, electrically connected to each other. The second top wiring layer L2 in the second chip C2 is made of copper, and the second buffer layer 53 is consist of a tantalum layer and a tantalum nitride layer. The third top wiring layer L3 in the third chip C3 is made of aluminum, and the third composite buffer layer 54 is consist of a titanium layer, a titanium nitride layer, a tantalum layer, and a tantalum nitride layer.

Furthermore, the present invention also provides a method for manufacturing a semiconductor structure with a hybrid bond contact, which includes forming a first hybrid bond contact HB, located in a dielectric layer 42, wherein the first hybrid bond contact HB is made of copper; forming a first top wiring layer L1, located in the dielectric layer 42 and below the first hybrid bond contact HB, wherein the first top wiring layer L1 is made of aluminum; and forming a first composite buffer layer (i.e., the titanium layer 12, the titanium nitride layer 14, the tantalum nitride layer 16, and the tantalum layer 18 in FIG. 2), located between the first hybrid bond contact HB and the first top wiring layer L1. From a cross-sectional view, the first composite buffer layer covers two sidewalls and bottom of the first hybrid bond contact HB, and the first composite buffer layer is consist of a titanium layer 12, a titanium nitride layer 14, a tantalum nitride layer 16, and a tantalum layer 18.

In summary, the present invention provides a semiconductor structure with a hybrid bond contact and its manufacturing method, characterized by the addition of a buffer layer with a four-layer structure between copper components and aluminum components at their interface.

This buffer layer consists of titanium layer, titanium nitride layer, tantalum nitride layer, and tantalum layer. Additionally, during heating, an aluminum-titanium layer is formed between the aluminum component and the titanium layer. According to the experiments conducted by the applicants, setting up these buffer layers can effectively reduce the interface resistance between copper components and aluminum components. Furthermore, the formed aluminum-titanium layer can effectively block the diffusion of aluminum atoms in the aluminum component to other components during the manufacturing process, thereby affecting electrical properties. Therefore, the structure and method provided by the present invention have the advantage of improving the quality and yield of the components.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure containing a hybrid bond contact, comprising:
a first hybrid bond contact located in a dielectric layer, wherein the first hybrid bond contact is made of copper;
a first top wiring layer located in the dielectric layer and below the first hybrid bond contact, wherein the first top wiring layer is made of aluminum;
a first composite buffer layer located between the first hybrid bond contact and the first top wiring layer, wherein, from a cross-sectional view, the first composite buffer layer covers two sidewalls and a bottom of the first hybrid bond contact, and the first composite buffer layer is consist of a titanium layer, a titanium nitride layer, a tantalum nitride layer, and a tantalum layer.

2. The semiconductor structure containing a hybrid bond contact according to claim 1, wherein in the first composite buffer layer, the titanium layer, the titanium nitride layer, the tantalum nitride layer, and the tantalum layer are arranged from bottom to top.

3. The semiconductor structure containing a hybrid bond contact according to claim 1, further comprising an aluminum-titanium (TiAl₃) layer located between the first composite buffer layer and the first top wiring layer.

4. The semiconductor structure containing a hybrid bond contact according to claim 3, wherein the aluminum-titanium (TiAl₃) layer directly contacts the first top wiring layer and a bottom surface of the titanium layer in the first composite buffer layer.

5. The semiconductor structure containing a hybrid bond contact according to claim 3, wherein the aluminum-titanium (TiAl₃) layer does not contact two sidewalls of the titanium layer in the first composite buffer layer.

6. The semiconductor structure containing a hybrid bond contact according to claim 1, further comprising a wiring layer located below the first top wiring layer, wherein the wiring layer is made of copper.

7. The semiconductor structure containing a hybrid bond contact according to claim 1, wherein the first hybrid bond contact includes an upper portion and a lower portion, wherein a width of the upper portion is greater than a width of the lower portion, and the first composite buffer layer covers a bottom surface and two sidewalls of the lower portion.

8. The semiconductor structure containing a hybrid bond contact according to claim 7, further comprising another buffer layer covering a bottom surface and two sidewalls of the upper portion of the first hybrid bond contact, wherein the another buffer layer is consist of a tantalum layer and a tantalum nitride layer, and does not contain a titanium layer or a titanium nitride layer.

9. The semiconductor structure containing a hybrid bond contact according to claim 1, wherein the first hybrid bond contact, the first top wiring layer, and the first composite buffer layer are located within a first chip, and further comprising a second chip and a third chip, wherein the size of the first chip is larger than that of the second chip and the third chip, and the first chip is bonded to both the second chip and the third chip simultaneously.

10. The semiconductor structure containing a hybrid bond contact according to claim 9, wherein the second chip includes a second hybrid bond contact, a second top wiring layer, and a second buffer layer electrically connected to each other, the third chip includes a third hybrid bond contact, a third top wiring layer, and a third composite buffer layer electrically connected to each other, wherein the second top wiring layer in the second chip is made of copper, the second buffer layer is consist of a tantalum layer and a tantalum nitride layer, the third top wiring layer in the third chip is made of aluminum, and the third composite buffer layer is consist of a titanium layer, a titanium nitride layer, a tantalum layer, and a tantalum nitride layer.

11. A method for manufacturing a semiconductor structure containing a hybrid bond contact, comprising:
forming a first hybrid bond contact located in a dielectric layer, wherein the first hybrid bond contact is made of copper;
forming a first top wiring layer located in the dielectric layer and below the first hybrid bond contact, wherein the first top wiring layer is made of aluminum;
forming a first composite buffer layer located between the first hybrid bond contact and the first top wiring layer, wherein, from a cross-sectional view, the first composite buffer layer covers two sidewalls and a bottom of the first hybrid bond contact, and the first composite buffer layer is consist of a titanium layer, a titanium nitride layer, a tantalum nitride layer, and a tantalum layer.

12. The method for manufacturing a semiconductor structure containing a hybrid bond contact according to claim 11, wherein in the first composite buffer layer, the titanium layer, the titanium nitride layer, the tantalum nitride layer, and the tantalum layer are arranged from bottom to top.

13. The method for manufacturing a semiconductor structure containing a hybrid bond contact according to claim 11, further comprising forming an aluminum-titanium (TiAl₃) layer located between the first composite buffer layer and the first top wiring layer.

14. The method for manufacturing a semiconductor structure containing a hybrid bond contact according to claim 13, wherein the aluminum-titanium (TiAl₃) layer directly contacts the first top wiring layer and a bottom surface of the titanium layer in the first composite buffer layer.

15. The method for manufacturing a semiconductor structure containing a hybrid bond contact according to claim 13, wherein the aluminum-titanium (TiAl₃) layer does not contact two sidewalls of the titanium layer in the first composite buffer layer.

16. The method for manufacturing a semiconductor structure containing a hybrid bond contact according to claim 11, further comprising forming a wiring layer located below the first top wiring layer, wherein the wiring layer is made of copper.

17. The method for manufacturing a semiconductor structure containing a hybrid bond contact according to claim 11, wherein the first hybrid bond contact includes an upper portion and a lower portion, wherein a width of the upper portion is greater than a width of the lower portion, and the first composite buffer layer covers the bottom surface and sidewalls of the lower portion.

18. The method for manufacturing a semiconductor structure containing a hybrid bond contact according to claim 17, further comprising forming another buffer layer covering a bottom surface and two sidewalls of the upper portion of the first hybrid bond contact, wherein the another buffer layer is consist of a tantalum layer and a tantalum nitride layer, and does not contain a titanium layer or a titanium nitride layer.

19. The method for manufacturing a semiconductor structure containing a hybrid bond contact according to claim 11, wherein the first hybrid bond contact, the first top wiring layer, and the first composite buffer layer are located within a first chip, and further comprising a second chip and a third chip, wherein the size of the first chip is larger than that of the second chip and the third chip, and the first chip is bonded to both the second chip and the third chip simultaneously.

20. The method for manufacturing a semiconductor structure containing a hybrid bond contact according to claim 19, wherein the second chip includes a second hybrid bond contact, a second top wiring layer, and a second buffer layer electrically connected to each other, the third chip includes a third hybrid bond contact, a third top wiring layer, and a third composite buffer layer electrically connected to each other, wherein the second top wiring layer in the second chip is made of copper, the second buffer layer is consist of a tantalum layer and a tantalum nitride layer, the third top wiring layer in the third chip is made of aluminum, and the third composite buffer layer is consist of a titanium layer, a titanium nitride layer, a tantalum layer, and a tantalum nitride layer.
